(19) United States
(12) Patent Application Publication
(10) Pub. No.: US 2026/0204298 A1
(43) Pub. Date: Jul. 16, 2026

(54) SEMICONDUCTOR MEMORY DEVICE AND METHOD OF OPERATING MEMORY SYSTEM

(71) Applicant: SAMSUNG ELECTRONICS CO., LTD., Suwon-si (KR)

(72) Inventor: Jongpil Son, Suwon-si (KR)

(21) Appl. No.: 19/275,005

(22) Filed: Jul. 21, 2025

(30) Foreign Application Priority Data
Jan. 16, 2025 (KR) 10-2025-0006988

(51) Int. Cl. G11C 5/06; G11C 11/4076; G11C 11/408; G11C 11/4096

(52) U.S. Cl. CPC G11C 5/063; G11C 11/4076; G11C 11/4085; G11C 11/4096

(57) ABSTRACT

A semiconductor memory device includes a plurality of memory cells connected to a plurality of wordlines and a plurality of bitlines. The semiconductor memory device is configured to control activation of a selected wordline among the plurality of wordlines based on an activation command, a read precharge command, and a write precharge command that are transmitted from a memory controller, activate the selected wordline based on the activation command and deactivate the selected wordline after a first activation reference time has elapsed from a time point of activating the selected wordline, maintain the selected wordline in a deactivated state when the read precharge command is received, and reactivate the selected wordline when the write precharge command is received.

### CROSS-REFERENCE TO RELATED APPLICATION

This U.S. non-provisional application claims priority under 35 USC § 119 to Korean Patent Application No. 10-2025-0006988, filed on Jan. 16, 2025, in the Korean Intellectual Property Office (KIPO), the entirety of which is incorporated by reference herein.

### BACKGROUND

Semiconductor memory devices may be broadly categorized into volatile memory devices and nonvolatile memory devices. Volatile memory (e.g., DRAM or SRAM) devices have fast read and write times, but the data stored in them is lost if the power supply is interrupted. Nonvolatile memory devices, on the other hand, may retain data even if the power supply is interrupted.

A prime example of a volatile memory device is a dynamic random access memory (DRAM) device. A memory cell in DRAM device may consist of one N-type metal oxide semiconductor (NMOS) transistor that acts as a switch and one capacitor that stores charge (data). Depending on the presence or absence of charge stored on the capacitor in the memory cell (i.e., whether the terminal voltage of the cell capacitor is high or low), the binary information “1” or “0” may be identified. The memory cell may be connected to a wordline and a bitline. The bitline may be connected to a bitline sense amplifier. The bitline sense amplifier may sense data stored in the memory cell or store data in the memory cell via the bitline based on a voltage applied to the wordline.

### SUMMARY

A semiconductor memory device activates a selected wordline corresponding to an access address and performs read and write operations on memory cells connected to the activated selected wordline. At this time, various disturbances may occur inside the semiconductor memory device due to the high voltage applied to the selected wordline, which degrades the reliability of the semiconductor memory device.

Some aspects of this disclosure provide semiconductor memory devices, memory systems including the semiconductor memory devices, and methods of operating the semiconductor memory devices and the memory systems, which provide improved performance and reliability.

According to some implementations of the present disclosure, a semiconductor memory device includes a plurality of memory cells connected to a plurality of wordlines and a plurality of bitlines. The semiconductor memory device is configured to control activation of a selected wordline among the plurality of wordlines based on an activation command, a read precharge command, and a write precharge command that are transmitted from a memory controller, activate the selected wordline based on the activation command and deactivate the selected wordline after a first activation reference time has elapsed from a time point of activating the selected wordline, maintain the selected wordline in a deactivated state when the read precharge command is received, and reactivate the selected wordline when the write precharge command is received.

According to some implementations of the present disclosure, a memory system includes a semiconductor memory device including a plurality of memory cells connected to a plurality of wordlines and a plurality of bitlines, and a memory controller configured to control the semiconductor memory device. The memory controller is configured to transmit an activation command to the semiconductor memory device, after transmitting the activation command, transmit at least one of read commands and write commands to the semiconductor memory device, when the memory controller transmits at least one read command and transmits no write command after transmitting the activation command, transmits a read precharge command to the semiconductor memory device, and when the memory controller transmits at least one write command after transmitting the activation command, transmits a write precharge command to the semiconductor memory device. The semiconductor memory device is configured to control activation of a selected wordline among the plurality of wordlines based on the activation command, the read precharge command, and the write precharge command.

According to some implementations of the present disclosure, a method of operating a memory system including a semiconductor memory device and a memory controller configured to control the semiconductor memory device, includes, by the memory controller, an activation command to the semiconductor memory device, transmitting, by the memory controller, at least one of read commands and write commands to the semiconductor memory device, after transmitting the activation command, transmitting, by the memory controller, a read precharge command to the semiconductor memory device, when the memory controller transmits at least one read command and transmits no write command after transmitting the activation command, transmitting, by the memory controller, a write precharge command to the semiconductor memory device, when the memory controller transmits at least one write command after transmitting the activation command, and controlling, by the semiconductor memory device, activation of a selected wordline based on the activation command, the read precharge command, and the write precharge command.

The semiconductor memory devices, the memory systems, and the methods of operating the memory systems described herein may reduce disturbance inside the semiconductor memory device and improve the performance and reliability of the semiconductor memory devices by, for example, reducing the activation time of the selected wordline based on the read precharge command and the write precharge command.

### BRIEF DESCRIPTION OF THE DRAWINGS

FIG. 1 is a block diagram illustrating an example of a memory system.

FIG. 2 is a flowchart illustrating an example of a method of operating a memory system

FIG. 3 is a block diagram illustrating an example of a semiconductor memory device.

FIG. 4 is a diagram illustrating an example of a bank array included in a semiconductor memory device.

FIGS. 5 and 6 are diagrams illustrating examples of commands in a memory system.

FIG. 7 is a timing diagram illustrating an example of command-based wordline activation in a semiconductor memory device.

FIG. 8 is a flowchart illustrating an example of a method of operating a semiconductor memory device.

FIG. 9 is a timing diagram illustrating an example of an operation of a semiconductor memory device.

FIG. 10 is a flowchart illustrating an example of a method of operating a semiconductor memory device.

FIG. 11 is a timing diagram illustrating an example of an operation of a semiconductor memory device.

FIG. 12 is a timing diagram illustrating an example of operation of a semiconductor memory device.

FIG. 13 is a state diagram illustrating examples of overall operations of a semiconductor memory device.

FIGS. 14 and 15 are diagrams illustrating an example of a memory core circuit included in a semiconductor memory device.

FIG. 16 is a diagram illustrating an example of a bitline sense amplifier included in a semiconductor memory device.

FIG. 17 is a diagram illustrating an example of a sense amplifier included in the bitline sense amplifier of FIG. 16.

FIG. 18 is a timing diagram illustrating an example of operation of the bitline sense amplifier of FIG. 16.

FIG. 19 is a diagram illustrating an example of a stacked memory device.

FIG. 20 is a diagram illustrating an example of a stacked memory device.

FIG. 21 is a diagram illustrating an example of a structure of a semiconductor package including a semiconductor memory device.

FIG. 22 is a block diagram illustrating an example of a mobile system including a semiconductor memory device.

### DETAILED DESCRIPTION

Various examples will be described hereinafter with reference to the accompanying drawings. In the drawings, like numerals refer to like elements throughout, and repeated descriptions thereof may be omitted.

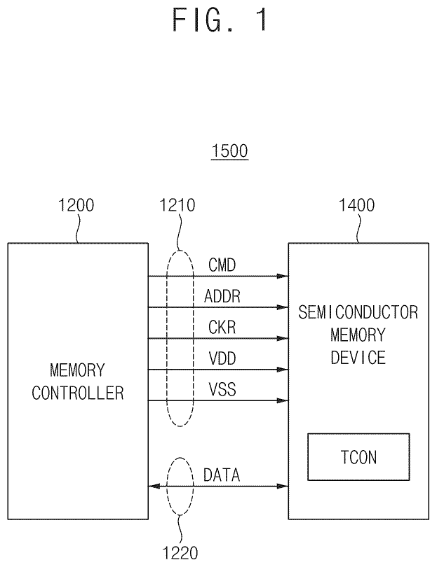

FIG. 1 is a block diagram illustrating an example of a memory system.

Referring to FIG. 1, a memory system 1500 includes a memory controller 1200 and a semiconductor memory device 1400. Each of the memory controller 1200 and the semiconductor memory device 1400 includes an interface for communicating with each other.

The interfaces may be connected through a control bus 1210 for transferring a command CMD, an access address ADDR, a clock signal CLK, a control signal, voltages VDD and VSS, etc., and a data bus 1220 for transmitting data.

Depending on the type of the semiconductor memory device 1400, the command CMD may be considered as including the access address ADDR. The memory controller 1200 generates commands CMD for controlling the semiconductor memory device 1400, and data DATA may be written to the semiconductor memory device 1400 or may be read out from the semiconductor memory device 1400 under control of the memory controller 1200.

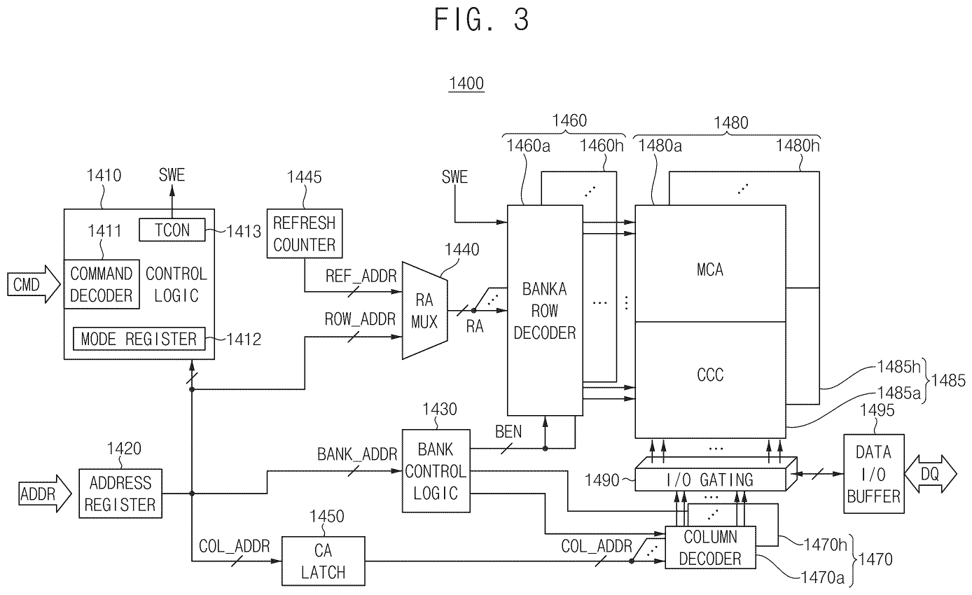

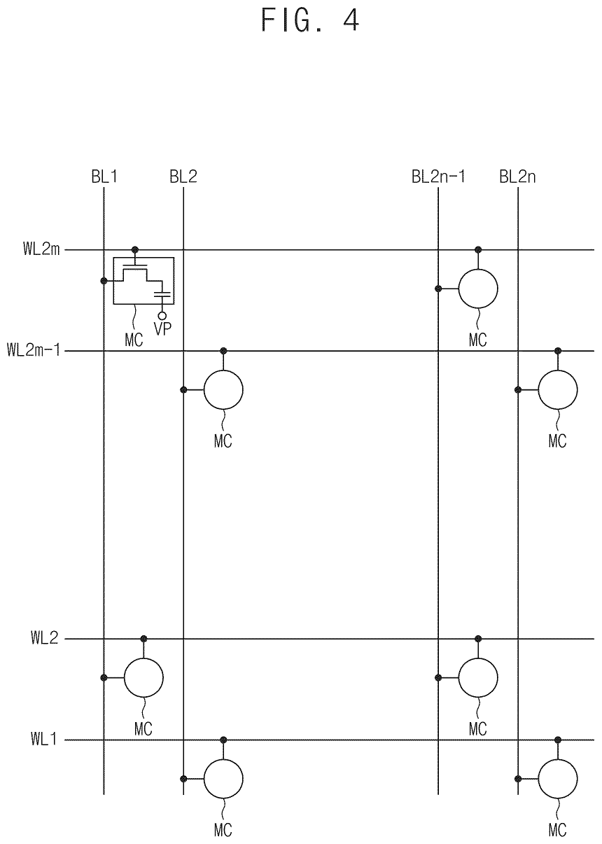

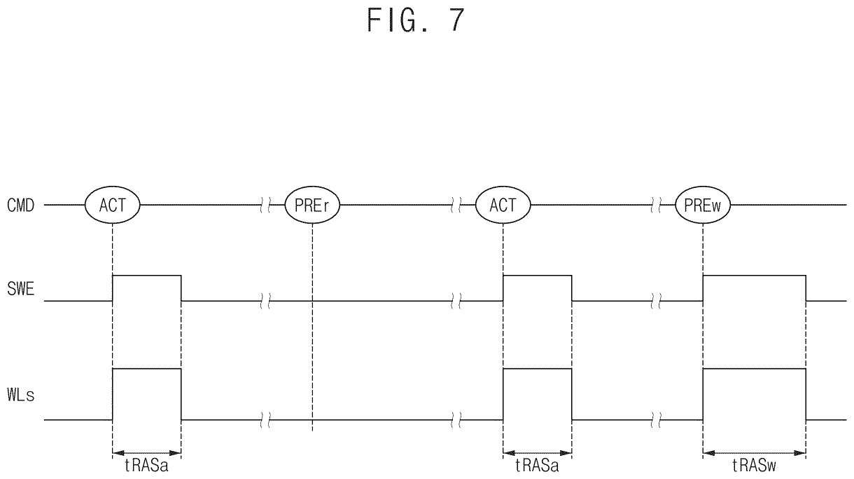

The semiconductor memory device 1400 may include a plurality of memory cells connected to a plurality of wordlines and a plurality of bitlines. Examples of the semiconductor memory device 1400 will be further described below with reference to FIGS. 3 and 4. Hereinafter, for convenience of illustration and description, it is assumed that the semiconductor memory device 1400 is a dynamic random access memory (DRAM) device. However, the type of memory device is not limited thereto, and the semiconductor memory device 1400 may be any one of various memory devices such as SRAM, SDRAM, MRAM, FRAM, ReRAM, PRAM, etc., and the memory controller 1200 and the semiconductor memory device 1400 may communicate with each other based on at least one of various interfaces such as DDR4, DDR5, HBM, LPDDR, USB, MMC, PCI, PCI-E, ATA, SATA, PATA, SCSI, ESDI, IDE, etc. In some implementations, the semiconductor memory device 1400 may include a timing controller TCON. As will be described below with reference to FIG. 7, the timing controller TCON may control activation of a selected wordline based on the commands received from the memory controller 1200.

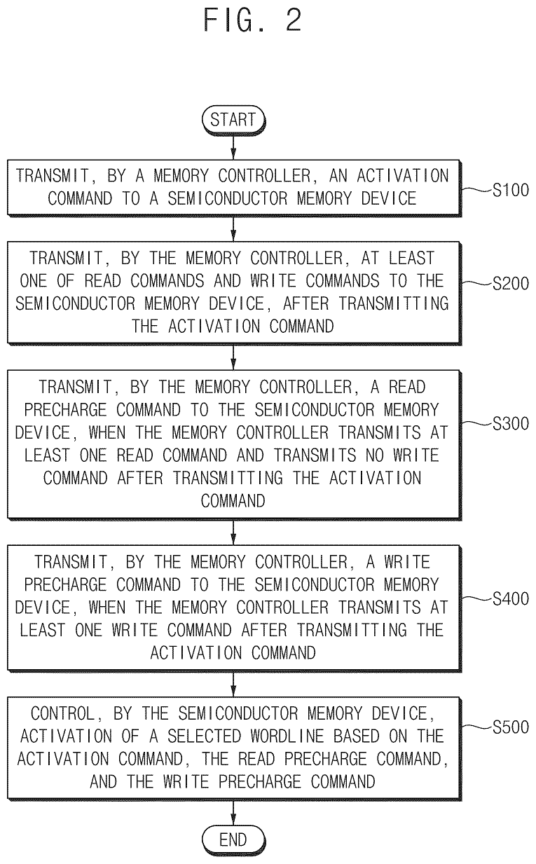

FIG. 2 is a flowchart illustrating an example of a method of operating a memory system

Referring to FIGS. 1 and 2, the memory controller 1200 may transmit an activation command to the semiconductor memory device 1400 (S100)

The memory controller 1200 may, after transmitting the activation command, transmit at least one of read commands and write commands to the semiconductor memory device 1400 (S200).

The memory controller 1200 may transmit a read precharge command to the semiconductor memory device 1400, when the memory controller 1200 has transmitted at least one of the read commands and no write command after transmitting the activation command (S300).

On the other hand, the memory controller 1200 may transmit a write precharge command to the semiconductor memory device 1400 when the memory controller 1200 has transmitted at least one write command after transmitting the activation command (S400).

The semiconductor memory device 1400 may control activation of a selected wordline of the plurality of wordlines based on the activation command, the read precharge command, and the write precharge command (S500).

FIG. 3 is a block diagram illustrating an example of a semiconductor memory device.

Referring to FIG. 3, a semiconductor memory device 1400 includes a control logic 1410, an address register 1420, a bank control logic 1430, a row address multiplexer 1440, a column address latch 1450, a row decoder 1460, a column decoder 1470, a memory cell array MCA 1480, a core control circuit CCC 1485, an input-output (I/O) gating circuit 1490, a data input-output (I/O) buffer 1495, and a refresh counter 1445.

The memory cell array 1480 may include a plurality of bank arrays 1480a-1480h. The row decoder 1460 may include a plurality of bank row decoders 1460a-1460h respectively coupled to the bank arrays 1480a-1480h. The column decoder 1470 may include a plurality of bank column decoders 1470a-1470h respectively coupled to the bank arrays 1480a-1480h, and the core control circuit 1485 may include a plurality of bank core control circuits 1485a-1485h respectively coupled to the bank arrays 1480a-1480h.

The address register 1420 may receive an address ADDR including a bank address BANK_ADDR, a row address ROW_ADDR and a column address COL_ADDR from a memory controller. The address register 1420 may provide the received bank address BANK_ADDR to the bank control logic 1430 and may provide the received row address ROW_ADDR to the row address multiplexer 1440. In addition, the address register 1420 may provide the received column address COL_ADDR to the column address latch 1450.

The bank control logic 1430 may generate bank control signals in response to the bank address BANK_ADDR. The bank control signals may include bank enable signals BEN to activate a selected memory bank corresponding to the bank address BANK_ADDR. One of the bank row decoders 1460a-460h corresponding to the bank address BANK_ADDR may be activated in response to the bank control signals, and one of the bank column decoders 1470a-1470h corresponding to the bank address BANK_ADDR may be activated in response to the bank control signals.

The row address multiplexer 1440 may receive the row address ROW_ADDR from the address register 1420 and may receive a refresh row address REF_ADDR from the refresh counter 1445. The row address multiplexer 1440 may selectively output the row address ROW_ADDR or the refresh row address REF_ADDR as a row address RA. The row address RA that is output from the row address multiplexer 1440 may be applied to the bank row decoders 1460a-1460h.

The activated one of the bank row decoders 1460a-1460h may decode the row address RA that is output from the row address multiplexer 1440 and may activate a wordline corresponding to the row address RA. For example, the activated bank row decoder may apply a wordline driving voltage to a selected wordline corresponding to the row address RA.

The column address latch 1450 may receive the column address COL_ADDR from the address register 1420 and may temporarily store the received column address COL_ADDR. In some implementations, in a burst mode, the column address latch 1450 may generate column addresses that increment from the received column address COL_ADDR. The column address latch 1450 may apply the temporarily stored or generated column address to the bank column decoders 1470a-1470h.

The activated one of the bank column decoders 1470a-1470h may decode the column address COL_ADDR that is output from the column address latch 1450 and may control the input-output I/O gating circuit 1490 to output data corresponding to the column address COL_ADDR.

The I/O gating circuit 1490 may include circuits for gating input-output data. The I/O gating circuit 1490 may further include read data latches and write drivers. The read data latches are for storing data that is output from the bank arrays 1480a-1480h, and the write drivers are for writing data to the bank arrays 1480a-1480h.

Data to be read from one bank array of the bank arrays 1480a-1480h may be sensed by the core control circuit 1485 coupled to the one bank array from which the data is to be read and may be stored in the read data latches. The data stored in the read data latches may be provided to the memory controller via the data I/O buffer 1495. Data DQ to be written in one bank array of the bank arrays 1480a-1480h may be provided to the data I/O buffer 1495 from the memory controller. The write driver may write the data DQ in one bank array of the bank arrays 1480a-1480h.

The control logic 1410 may control operations of the semiconductor memory device 1400. For example, the control logic 1410 may generate control signals for the semiconductor memory device 1400 to perform a write operation or a read operation. The control logic 1410 may include a command decoder 1411 and mode registers 1412. The command decoder decodes a command CMD received from the memory controller, and the mode registers 1412 stores control values for controlling operations of the semiconductor memory device 1400.

In some implementations, the control logic 1410 may include a timing controller (TCON) 1413. As will be described below with reference to FIG. 7, the timing controller 1413 may generate a wordline enable signal SWE based on commands transmitted from the memory controller 1200. The row decoder 1460 may control activation of a selected wordline based on the wordline enable signal SWE. FIG. 3 illustrates an example in which the timing controller 1413 is included in the control logic 1410, but configurations are not limited thereto. For example, in some implementations, the timing controller 1413 may be implemented as separate hardware distinct from the control logic 1410.

FIG. 4 is a diagram illustrating an example of a bank array included in a semiconductor memory device.

Referring to FIG. 4, a bank array includes a plurality of wordlines WL1 through WL2m, where m is a binary integer, a plurality of bitlines BL1 through BL2n, where n is a binary integer, and a plurality of memory cells MC disposed at intersections between the wordlines WL1 through WL2m and the bitlines BL1 through BL2n. As shown in FIG. 4, each memory cell MC may have a DRAM cell structure. The memory cells MC may include a cell capacitor connected to a plate voltage VP and a cell transistor connected between each bitline and the cell capacitor and the gate electrode of the cell transistor is connected to each wordline. The wordlines to which the memory cells MC are connected may be defined as rows of the bank array, and the bitlines to which the memory cells MC are connected may be defined as columns of the bank array.

The semiconductor memory device may be a DRAM device as described with reference to FIGS. 3 and 4, but the memory type is not limited to any particular type of memory.

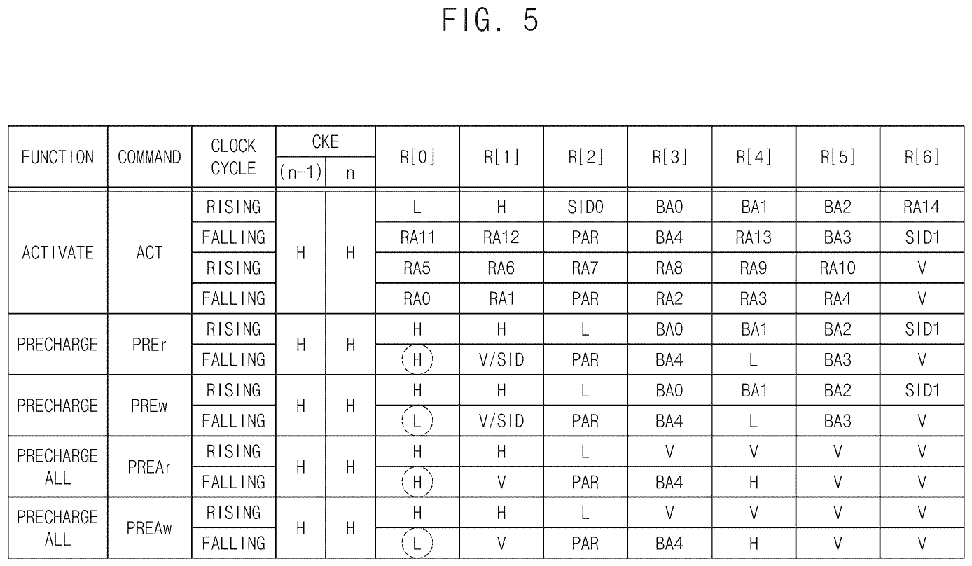

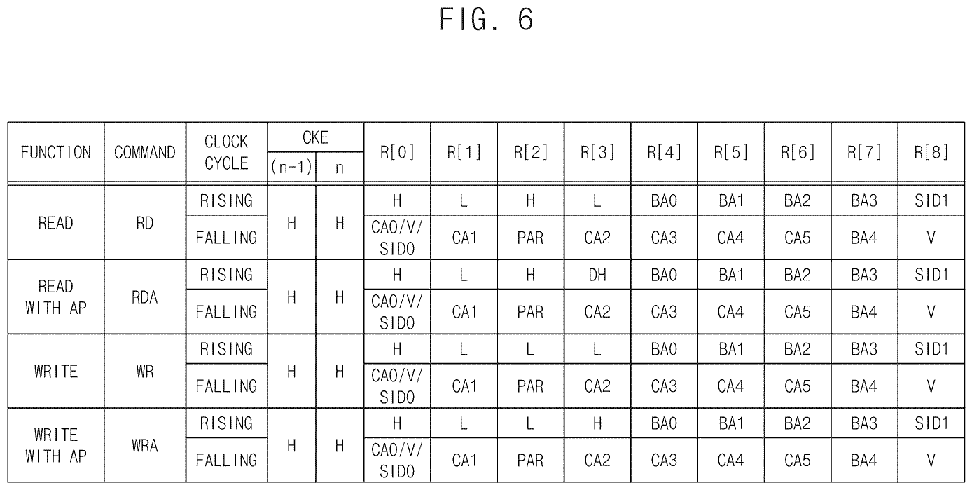

FIGS. 5 and 6 are diagrams illustrating examples of commands in a memory system. FIGS. 5 and 6 illustrate a portion of commands according to a standard for high bandwidth memory (HBM). A portion of row commands are shown in FIG. 5, and a portion of column commands are shown in FIG. 6. FIGS. 5 and 6 are intended to illustrate an example of how to distinguish between the read precharge command and the write precharge command, and commands within the scope of this disclosure are not limited to any particular memory standard, command format, or the like.

FIGS. 5 and 6 illustrate combinations of the (n−1)-th and n-th clock cycles of the clock enable signal CKE, the row address signals R[0]-R[6], and the column address signals C[0]-C[8], and the nth clock cycle of the clock enable signal (CKE) such that the combinations indicate an activation command ACT, precharge commands PREr, PREw, PREAr, and PREAw, read commands RD and RDA, and write commands WR and WRA. The precharge commands PREr and PREw indicate the precharge of each memory bank, and the precharge commands PREAr and PREAw indicate the precharge of all memory banks. The read commands RD and the write commands WR indicate operations without auto precharge AP, while the read commands RDA and write commands WRA indicate operations with auto precharge AP.

In FIGS. 5 and 6, H denotes logic high level, L denotes logic low level, RA0 through RA14 denote bits of a row address, CA0 through CA5 denote bits of a column address, BA0 through BA3 denote bits of a bank address, V denotes a reserved bit, which may be logic low level or logic high level (but not floating), and PAR denotes a parity signal.

In some implementations, as shown in FIG. 5, the logic level at the falling edge of the clock signal of the row address signal R[0] corresponding to one of the reserved bits in the HBM standard may be used as a flag bit to distinguish the read precharge commands PREr and PREAr from the write precharge commands PREw and PREAw. The command decoder 1411 of FIG. 3 may distinguish the read precharge commands PREr and PREAr from the write precharge commands PREw and PREAw based on the logic level of the flag bit shown as dotted circles in FIG. 5. For example, if the row address signal R[0] is in the logic high level H at the falling edge of the clock signal, the commands correspond to the read precharge commands PREr and PREAr. On the other hand, if the row address signal R[0] is in the logic low level L at the falling edge of the clock signal, the commands correspond to the write precharge commands PREw and PREAw.

FIG. 7 is a timing diagram illustrating an example of command-based wordline activation in a semiconductor memory device.

Referring to FIGS. 3 and 7, the timing controller 1413 may generate a wordline enable signal SWE indicating the timing of activation of the selected wordline WLs based on an activation command ACT and a write precharge command PREw. The wordline enable signal SWE may be provided to the row decoder 1460, and the row decoder 1460 may enable and disable the selected wordline WLs in synchronization with the activation and deactivation of the wordline enable signal SWE. The timing controller 1413 may include components such as clock counters, flip-flops, etc. for generating the wordline enable signal SWE of FIG. 7. The timing controller 1413 may have any suitable configuration for generating the wordline enable signal SWE as described herein.

The timing controller 1413 may enable the wordline enable signal SWE during a first activation reference time tRASa based on the activation command ACT. The row decoder 1460 may enable the selected wordline WLs based on the activation command ACT and disable the selected wordline WLs after the first activation reference time tRASa has elapsed from the time point of enabling the selected wordline WLs.

Further, the timing controller 1413 may activate the wordline enable signal SWE based on the write precharge command PREw during a second activation reference time tRASw. The row decoder 1460 may reactivate the selected wordline WLs based on the write precharge command PREw and deactivate the selected wordline WLs again after the second activation reference time tRASw has elapsed from the time point of deactivating the selected wordline WLs.

On the other hand, the timing controller 1413 may ignore the read precharge command PREr, and thus, the wordline enable signal SWE may remain deactivated.

As such, the semiconductor memory device 1400 may maintain the selected wordline WLs in the deactivated state upon receipt of the read precharge command PREr from the memory controller 1200, and may reactivate the selected wordline WLs upon receipt of the write precharge command PREw from the memory controller 1200.

The first activation reference time tRASa and the second activation reference time tRASw may be the minimum time required for the activation of the selected wordline WLs, the charge sharing between the memory cell and the precharged bitline, the sensing operation of the bitline sense amplifier, and the re-charging of the memory cell based on the voltage on the bitline.

In some implementations, the first activation reference time tRASa and the second activation reference time tRASw may be determined based on a control value stored in a mode register among the mode registers 1412. The control value may correspond to a cycle count of the clock signal, and the control value may be provided to the semiconductor memory device 1400 via a mode register write command transmitted from the memory controller 1200.

According to some implementations, the first activation reference time tRASa and the second activation reference time tRASw may be the same or may be different. As described below, during the second activation reference time tRASw, a write operation may be performed to store write data into memory cells connected to the selected wordline WLs. Depending on the operation settings of the semiconductor memory device 1400, the write data may be loaded onto the bitlines during the second activation reference time tRASw. In this case, the second activation reference time tRASw may be set longer than the first activation reference time tRASa to secure the time to load the write data onto the bitlines.

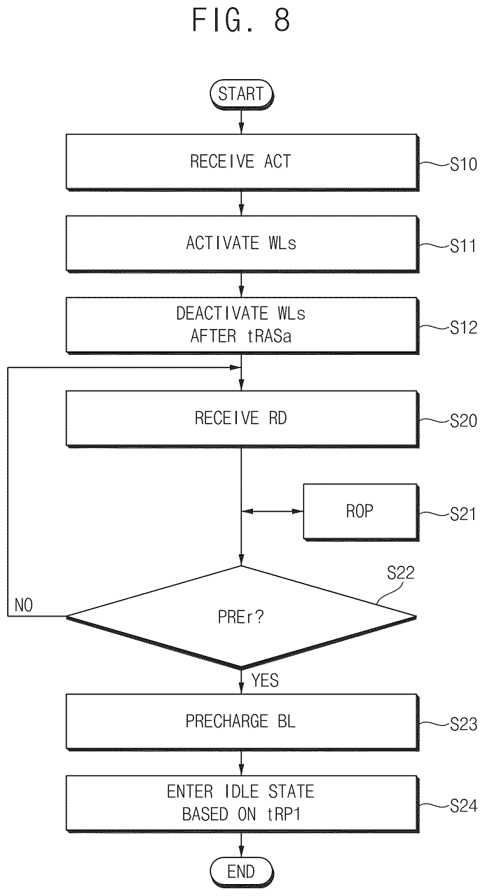

FIG. 8 is a flowchart illustrating an example of a method of operating a semiconductor memory device.

Referring to FIGS. 1, 3 and 8, the semiconductor memory device 1400 may receive an activation command ACT from the memory controller 1200 (S10) and may activate the selected wordline WLs based on the received activation command ACT (S11). Then, as described with reference to FIG. 7, the semiconductor memory device 1400 may deactivate the selected wordline WLs after the first activation reference time tRASa has elapsed (S12), regardless of the commands from the memory controller 1200.

With the selected wordline WLs deactivated, the semiconductor memory device 1400 may receive a read command RD (S20). The semiconductor memory device 1400 may perform a read operation ROP based on the read command RD received from the memory controller 1200 (S21). Here, the read operation ROP may represent reading out data from the memory cells connected to the selected wordline WLs and transmitting the read data to the memory controller 1200.

Until a read precharge command PREr is received (S22: NO), the semiconductor memory device 1400 may repeat receiving other read commands RD (S20) and performing the read operation ROP (S21).

When the read precharge command PREr is received (S22: YES), the semiconductor memory device 1400 may precharge the bitlines BL (S23).

In addition, upon receipt of the read precharge command PREr (S22: YES), the semiconductor memory device 1400 may enter an idle state based on the first precharge reference time tRP1. For example, the first precharge reference time tRP1 may be a time interval that is to be guaranteed from the time point of receiving the read precharge command PREr to the time point of receiving a next activation command ACT, for the precharge operation or other operations (e.g., a data output operation). For example, the semiconductor memory device 1400 may complete operations according to the read commands RD during the first precharge reference time tRP1 and then enter the idle state by precharging bitlines.

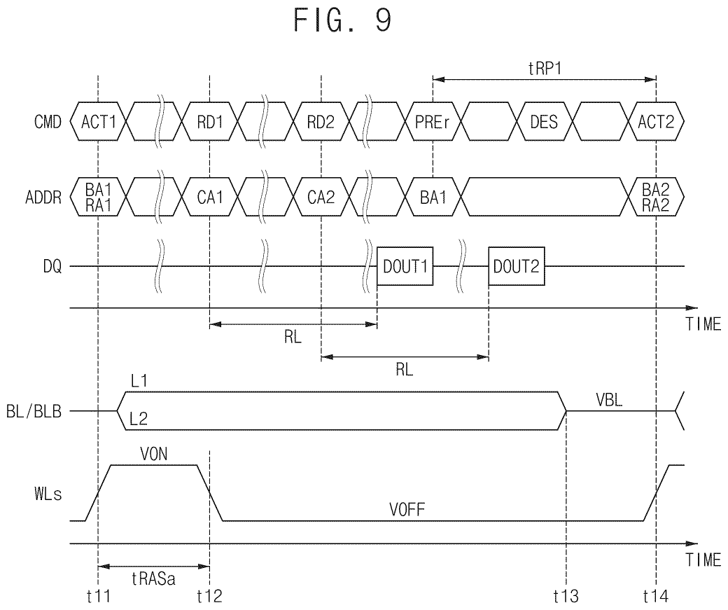

FIG. 9 is a timing diagram illustrating an example of an operation of a semiconductor memory device according to the method of FIG. 8.

FIG. 9 illustrates an example in which a write command WR is not received between an activation command ACT1 and a read precharge command PREr. For convenience of illustration and description, it is assumed that two read commands RD1 and RD2 are received between the first activation command ACT1 and the read precharge command PREr, but the number of commands is not limited thereto.

Referring to FIGS. 1, 3 and 9, at time point t11, the semiconductor memory device 1400 may receive a first activation command ACT1, a first bank address BA1, and a first row address RA1 from the memory controller 1200. In response to the first activation command ACT1, the semiconductor memory device 1400 may determine the selected wordline WLs corresponding to the first bank address BA1 and the first row address RA1, and may activate the selected wordline WLs. For example, as shown in FIG. 9, the semiconductor memory device 1400 may apply a high voltage VON to the selected wordline WLs to activate the selected wordline WLs.

As the semiconductor memory device 1400 activates the selected wordline WLs, operations such as a charge sharing operation, a sensing operation, a re-storing operation, and the like may be performed with respect to the memory cells connected to the selected wordline WLs. For example, during activation of the selected wordline WLs, based on data stored in a memory cell connected to the selected wordline WLs and the bitlines BL, the voltages of the bitline BL and the complementary bitline BLB of the semiconductor memory device 1400 may change to a first level L1 and a second level L2, respectively, as shown in FIG. 9.

The semiconductor memory device 1400 may deactivate the selected wordline WLs at time point t12 after the first activation reference time tRASa has elapsed from time point t11 when the first activation command ACT1 is received. For example, the semiconductor memory device 1400 may apply a low voltage VOFF to the selected wordline WLs at time point t12 after the first activation reference time tRASa has elapsed from time point t11 when the first activation command ACT1 is received. In some implementations, the first activation reference time tRASa may be the minimum time required for data stored in the memory cells connected to the selected wordline WLs to be stored in the data input-output buffer 1495. In some implementations, the first activation reference time tRASa may be the minimum time required for the activation operation of the selected wordline WLs, the charge sharing operation between the memory cells and the precharged bitlines, the sensing operation of the bitline sense amplifier, and the re-storing operation of the memory cells based on the voltage of the bitlines.

Subsequently, the semiconductor memory device 1400 may receive a first read command RD1 and a first column address CA1 from the memory controller 1200, and may receive a second read command RD2 and a second column address CA2. The semiconductor memory device 1400 may output the corresponding first and second read data DOUT1 and DOUT2 to the data pins DQ in response to the received first read command RD1 and the first column address CA1, and the second read command RD2 and the second column address CA2. The semiconductor memory device 1400 may output the first read data DOUT1 after a read latency RL has elapsed from the time point of receiving the first output command RD1, and may output the second read data DOUT2 after the read latency RL has elapsed from the time point of receiving the second output command RD2.

In some implementations, as shown in FIG. 9, even when the selected wordline WLs is deactivated, the voltages on the bitline BL and the complementary bitline BLB are maintained, such that the output of the first and second read data DOUT1 and DOUT2 may be performed.

The semiconductor memory device 1400 may receive the read precharge command PREr from the memory controller 1200, and may perform the precharge operation in response to the received read precharge command PREr. As will be described below, the semiconductor memory device 1400 may perform the precharge operation by applying a precharge voltage VBL to the bitline BL and the complementary bitline BLB at time point t13.

At time point t14, the semiconductor memory device 1400 may receive a second activation command ACT2, a second bank address BA2, and a second row address RA2 from the memory controller 1200 after the first precharge reference time tRP1 has elapsed from the time point of receiving the read precharge command PREr.

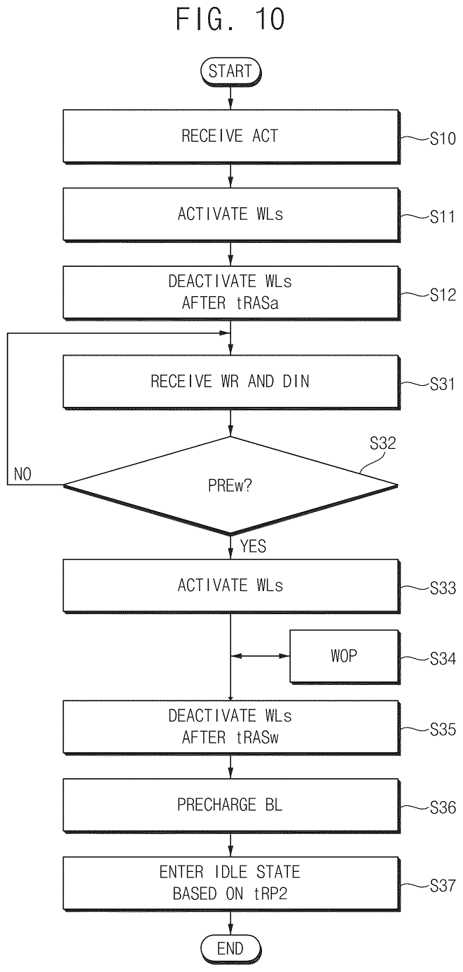

FIG. 10 is a flowchart illustrating an example of a method of operating a semiconductor memory device.

Referring to FIGS. 1, 3 and 10, the semiconductor memory device 1400 may receive an activation command ACT from the memory controller 1200 (S10) and may activate the selected wordline WLs based on the received activation command ACT (S11). Then, as described with reference to FIG. 7, the semiconductor memory device 1400 may deactivate the selected wordline WLs after the first activation reference time tRASa has elapsed (S12), regardless of the commands transmitted from the memory controller 1200.

With the selected wordline WLs deactivated, the semiconductor memory device 1400 may receive the write command WR and write data DIN (S31). The semiconductor memory device 1400 may store the received write data DIN in the data input-output buffer 1495 or in the corresponding bitline sense amplifiers of the core control circuit 1485.

Until a write precharge command PREw is received (S32: NO), the semiconductor memory device 1400 may repeat reception of the write command WR and the reception of the write data DIN (S31).

When the write precharge command PREw is received (S32: YES), the semiconductor memory device 1400 may reactivate the selected wordline WLs (S33). Then, as described with reference to FIG. 7, the semiconductor memory device 1400 may deactivate the selected wordline WLs again (S35) after the second activation reference time tRASw has elapsed, regardless of commands transmitted from the memory controller 1200. The semiconductor memory device 1400 may perform a write operation WOP during the second activation reference time tRASw after the selected wordline WLs are reactivated (S34). Here, the write operation WOP may represent storing the write data stored in the data input-output buffer 1495 or in the corresponding bitline sense amplifiers of the core control circuit 1485 into the memory cells connected to the selected wordline WLs.

After deactivating the selected wordline WLs again (S35), the semiconductor memory device 1400 may precharge the bitlines BL (S36).

Upon receipt of the write precharge command PREw (S32: YES), the semiconductor memory device 1400 may enter the idle state based on the second precharge reference time tRP2. For example, the second precharge reference time tRP2 may be a reference time that has to be guaranteed from the time point of receiving the write precharge command PREw to the time point of receiving the next activation command ACT, for a precharge operation or other operations (e.g., the write operation WOP). For example, the semiconductor memory device 1400 may complete the operation for the write command WR during the second precharge reference time tRP2, precharge the bitlines, and enter the idle state.

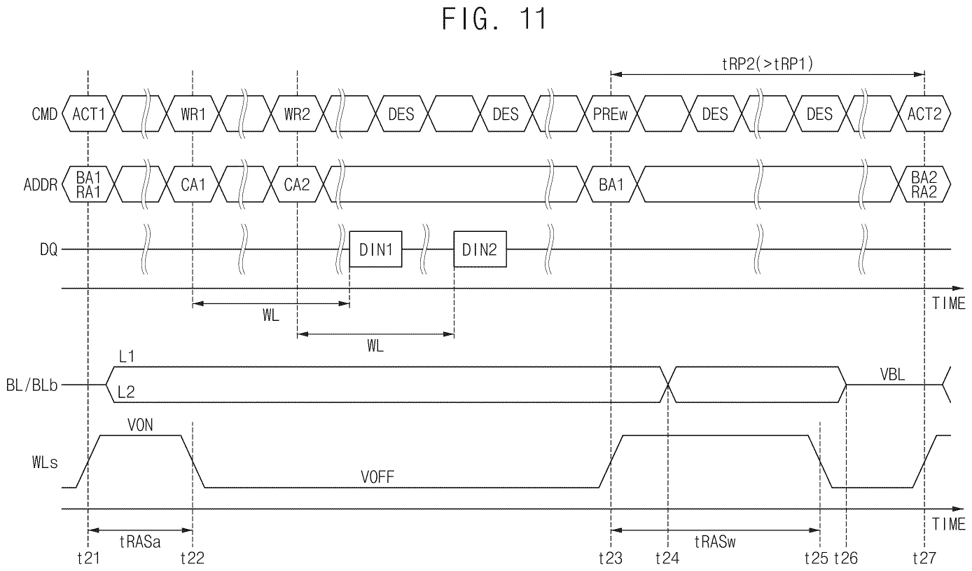

FIG. 11 is a timing diagram illustrating an example of operation of a semiconductor memory device according to the method of FIG. 10.

FIG. 11 illustrates an example in which a read command RD is not received between an activation command ACT1 and a write precharge command PREw. For convenience of illustration and description, it is assumed that two write commands WD1 and WD2 are received between the first activation command ACT1 and the write precharge command PREw, but the number of commands is not limited thereto.

Referring to FIGS. 1, 3 and 11, at time point t21, the semiconductor memory device 1400 may receive a first activation command ACT1, a first bank address BA1, and a first row address RA1 from the memory controller 1200. In response to the first activation command ACT1, the semiconductor memory device 1400 may select the selected wordline WLs corresponding to the first bank address BA1 and the first row address RA1, and may enable the selected wordline WLs. For example, as shown in FIG. 11, the semiconductor memory device 1400 may apply a high voltage VON to the selected wordline WLs to activate the selected wordline WLs.

As the semiconductor memory device 1400 activates the selected wordline WLs, operations such as charge sharing operations, sensing operations, re-storing operations, and the like may be performed with respect to the memory cells connected to the selected wordline WLs. For example, during activation of the selected wordline WLs, based on data stored in the memory cells connected to the selected wordline WLs and the bitlines BL, the voltages of the bitline BL and the complementary bitline BLB of the semiconductor memory device 1400 may change to a first level L1 and a second level L2, respectively, as shown in FIG. 11.

The semiconductor memory device 1400 may deactivate the selected wordline WLs at time point t22 after the first activation reference time tRASa has elapsed from the time point t21 when the first activation command ACT1 is received. For example, the semiconductor memory device 1400 may apply a low voltage VOFF to the selected wordline WLs at time point t22 after the first activation reference time tRASa has elapsed from the time point t21 when the first activation command ACT1 is received. In some implementations, the first activation reference time tRASa may be the minimum time required for data stored in the memory cells connected to the selected wordline WLs to be stored in the data input-output buffer 1495. In some implementations, the first activation reference time tRASa may be the minimum time required for the activation operation of the selected wordline WLs, the charge sharing operation between the memory cells and the precharged bitlines, the sensing operation of the bitline sense amplifier, and the re-storing operation of the memory cells based on the voltage of the bitlines.

Subsequently, the semiconductor memory device 1400 may receive a first write command WR1 and a first column address CA1 from the memory controller 1200, and may receive a second write command WR2 and a second column address CA2. The semiconductor memory device 1400 may receive the first write data DIN1 through the data pins DQ after a write latency WL has elapsed from the time point of receiving the first write command WR1, and may receive the second write data DIN2 through the data pins DQ after the write latency WL has elapsed from the time point of receiving the second write command WR2. The received write data DIN1 and DIN2 may be stored in the data input-output buffer 1495 or in the corresponding bitline sense amplifiers of the core control circuit 1485.

The semiconductor memory device 1400 may receive a write precharge command PREw and a first bank address BA1 from the memory controller 1200 at time point T23. In response to the write precharge command PREw, the semiconductor memory device 1400 may activate the selected wordline WLs of the first bank address BA1. The semiconductor memory device 1400 may deactivate the selected wordline WLs at time point t25 after the second activation reference time tRASw has elapsed from the time point t23 when the write precharge command PREw is received.

At time point t24 during the second activation reference time tRASw, the semiconductor memory device 1400 may perform the write operation by loading the first and second write data DIN1 and DIN2 into the corresponding bitlines BL and complementary bitlines BLB, respectively.

The semiconductor memory device 1400 may precharge the bitlines BL and complementary bitlines BLB with a precharge voltage VBL at time point t26 after deactivating the selected wordline WLs.

The semiconductor memory device 1400 may receive a second activation command ACT2, a second bank address BA2, and a second row address RA2 from the memory controller 1200 at time point t27 after a second precharge reference time tRP2 has elapsed from time point t23 of receiving the write precharge command PREw.

As described with reference to FIG. 9, no write command WR is received between the first activation command ACT1 and the read precharge command PREr, and the semiconductor memory device 1400 may receive the next second activation command ACT2 after the first precharge reference time tRP1 has elapsed from the time point of receiving the read precharge command PRE. As described with reference to FIG. 11, at least one write command WR is received between the first activation command ACT1 and the write precharge command PREw, and the semiconductor memory device 1400 may receive the next second activation command ACT2 after the second precharge reference time tRP2 has elapsed from the time point of receiving the write precharge command PREw, to secure time for the write operation. The second precharge reference time tRP2 may be longer than the first precharge reference time tRP1.

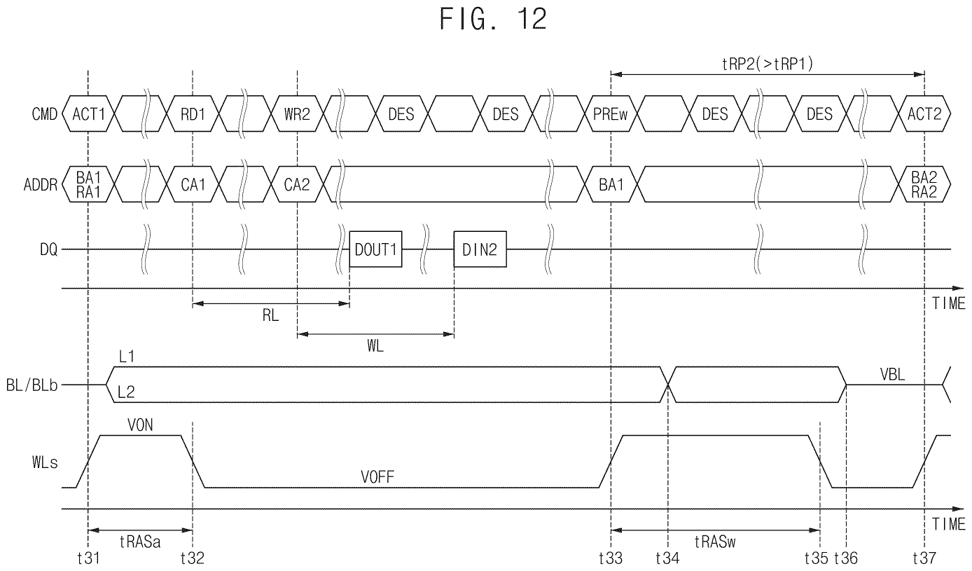

FIG. 12 is a timing diagram illustrating an example of operation of a semiconductor memory device.

FIG. 12 illustrates an example in which a read command RD and a write command WR are received between an activation command ACT1 and a write precharge command PREw. For convenience of illustration and description, it is assumed that one read command RD1 and one write command WD1 are received between the first activation command ACT1 and the write precharge command PREw, but the numbers of commands are not limited thereto.

Referring to FIGS. 1, 3 and 12, at time point t31, the semiconductor memory device 1400 may receive a first activation command ACT1, a first bank address BA1, and a first row address RA1 from the memory controller 1200. In response to the first activation command ACT1, the semiconductor memory device 1400 may determine the selected wordline WLs corresponding to the first bank address BA1 and the first row address RA1, and may activate the selected wordline WLs. For example, as shown in FIG. 12, the semiconductor memory device 1400 may apply a high voltage VON to activate the selected wordline WLs.

As the semiconductor memory device 1400 activates the selected wordline WLs, operations such as charge sharing operations, sensing operations, re-storing operations, and the like may be performed with respect to the memory cells connected to the selected wordline WLs. For example, during activation of the selected wordline WLs, based on data stored in the memory cells connected to the selected wordline WLs and the bitlines BL, the voltages of the bitlines BL and the complementary bitlines BLB of the semiconductor memory device 1400 may change to a first level L1 and a second level L2, respectively, as shown in FIG. 12.

The semiconductor memory device 1400 may deactivate the selected wordline WLs at time point t32, where a first activation reference time tRASa has elapsed from time point t31 when the first activation command ACT1 is received. For example, the semiconductor memory device 1400 may apply a low voltage VOFF to the selected wordline WLs at time point t32 after the first activation reference time tRASa has elapsed from time point t31 when the first activation command ACT1 is received. In some implementations, the first activation reference time tRASa may be the minimum time required for data stored in the memory cells connected to the selected wordline WLs to be stored in the data input-output buffer 1495. In some implementations, the first activation reference time tRASa may be the minimum time required for the activation operation of the selected wordline WLs, the charge sharing operation between the memory cells and the precharged bitlines, the sensing operation of the bitline sense amplifier, and the re-storing operation of the memory cells based on the voltage of the bitlines.

Subsequently, the semiconductor memory device 1400 may receive a first read command RD1 and a first column address CA1 from the memory controller 1200. The semiconductor memory device 1400 may output the first read data DOUT1 via the data pins DQ after the read latency RL has elapsed from the time point of receiving the first read command RD1. Subsequently, the semiconductor memory device 1400 may receive a second write command WR2 and a second column address CA2 from the memory controller 1200. The semiconductor memory device 1400 may receive the second write data DIN2 via the data pins DQ after the write latency WL has elapsed from the time point of receiving the second write command WR2. The received write data DIN2 may be stored in the data input-output buffer 1495 or in the corresponding bitline sense amplifiers of the core control circuit 1485.

The semiconductor memory device 1400 may receive a write precharge command PREw and a first bank address BA1 from the memory controller 1200 at time point T33. In response to the write precharge command PREw, the semiconductor memory device 1400 may reactivate the selected wordline WLs of the first bank address BA1. The semiconductor memory device 1400 may deactivate the selected wordline WLs at time point t35 after the second activation reference time tRASw has elapsed from time point t33 when the write precharge command PREw is received.

At time point t34 during the second activation reference time tRASw, the semiconductor memory device 1400 may perform the write operation by loading the second write data DIN2 into the corresponding bitline BL and the complementary bitline BLB, respectively.

The semiconductor memory device 1400 may precharge the bitlines BL and complementary bitlines BLB with a precharge voltage VBL at time point t36 after deactivating the selected wordline WLs.

The semiconductor memory device 1400 may receive the next second activation command ACT2, a second bank address BA2, and a second row address RA2 from the memory controller 1200 at time point t37 after the second precharge reference time tRP2 has elapsed from time point t33 of receiving the write precharge command PREw.

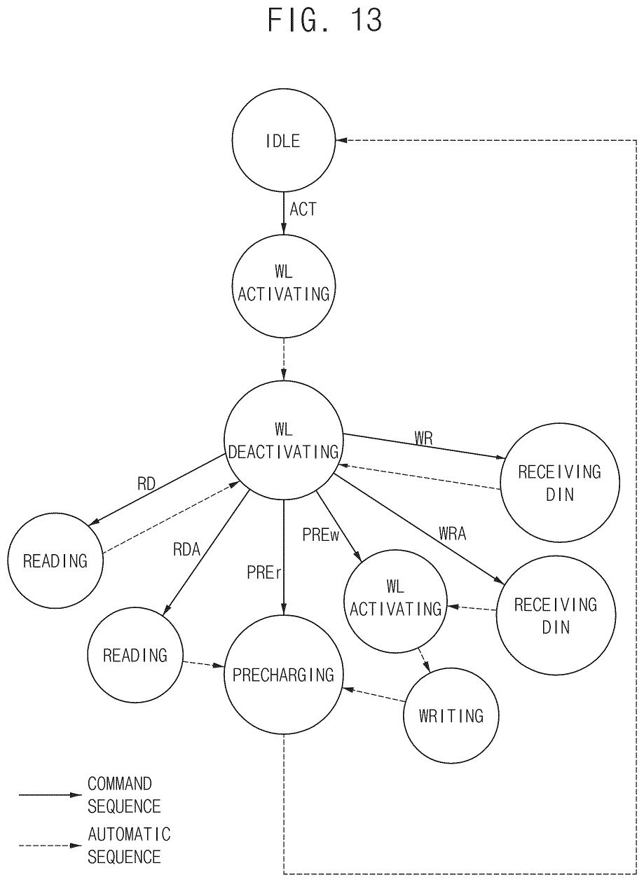

FIG. 13 is a state diagram illustrating an example of overall operations of a semiconductor memory device.

FIG. 13 shows an example of a state diagram of the semiconductor memory device 1400 of FIG. 1. For convenience of illustration and description, components that are not necessary to describe the operation or state of the semiconductor memory device 1400 are omitted. In FIG. 13, solid arrows indicate a command sequence that is performed in response to a command, and dashed arrows indicate an automatic sequence that is performed internally in the semiconductor memory device 1400 regardless of the command, or without receiving a corresponding command.

Referring to FIGS. 1 and 13, the semiconductor memory device 1400 in the idle state may enter the wordline activating state (WL Activating) in response to an activation command ACT. For example, the semiconductor memory device 1400 in the idle state may apply a high voltage VON to the selected wordline WLs in response to the activation command ACT and store the data stored in the memory cells connected to the selected wordline WLs into the data input-output buffer 1495 (or the bitline sense amplifiers of the core control circuit 1485). As another example, the semiconductor memory device 1400 in the idle state may apply a high voltage VON to the selected wordline WLs in response to an activation command ACT and perform operations such as charge sharing operations, sensing operations, re-storing operations, etc. with respect to the memory cells connected to the selected wordline WLs.

The semiconductor memory device 1400 in the wordline activating state may enter the wordline deactivating state (WL Deactivating) after the first activation reference time tRASa has elapsed. For example, the semiconductor memory device 1400 in the wordline activating state (WL Activating) may deactivate the activated wordline by applying a low voltage VOFF to the activated wordline after the first activation reference time tRASa has elapsed from the time point of receiving the activation command ACT.

When the semiconductor memory device 1400 receives a read command RD from the wordline deactivating state (WL Deactivating), the semiconductor memory device 1400 may advance to the reading state (Reading) and perform a data output operation. Subsequently, the semiconductor memory device 1400 may re-enter the wordline deactivating state (WL Deactivating).

While in the wordline deactivating state (WL Deactivating), the semiconductor memory device 1400 may respond to an auto-precharge read command RDA to enter the reading state (Reading) and enter the precharging state (Precharging) after completing the data output operation. Additionally, the semiconductor memory device 1400 may enter the precharging state (Precharging) in response to a read precharge command PREr from the wordline deactivating state (WL Deactivating).

The semiconductor memory device 1400 may enter a write data receiving state (Receiving DIN) in response to a write command WR in the wordline deactivating state (WL Deactivating) to perform a data receiving operation. Subsequently, the semiconductor memory device 1400 may re-enter the wordline deactivating state (WL Deactivating).

The semiconductor memory device 1400 may reenter the wordline activating state (WL Activating) from the wordline deactivating state (WL Deactivating) in response to an auto precharge write command WRA. The semiconductor memory device 1400 may enter the writing state from the wordline activating state (WL Activating) to perform a write operation, and may enter the precharging state (Precharging) upon completion of the write operation.

Further, the semiconductor memory device 1400 may reenter the wordline activating state (WL Activating) from the wordline deactivating state (WL Deactivating) in response to a write precharge command PREw. The semiconductor memory device 1400 may enter the writing state (Writing) from the wordline activating state (WL Activating) to perform a write operation, and may enter the precharging state (Precharging) upon completion of the write operation.

The semiconductor memory device 1400 in the precharging state (Precharging) may enter the idle state after performing the precharge operation. In some implementations, as described with reference to FIG. 9, the path from the reading state through the precharging state to the idle state may be performed during the first precharge reference time tRP1. In some implementations, as described with reference to FIG. 11, the path from the writing state through the precharging state to the idle state may be performed during the second precharge reference time tRP2. The second precharge reference time tRP2 may be longer than the first precharge reference time tRP1.

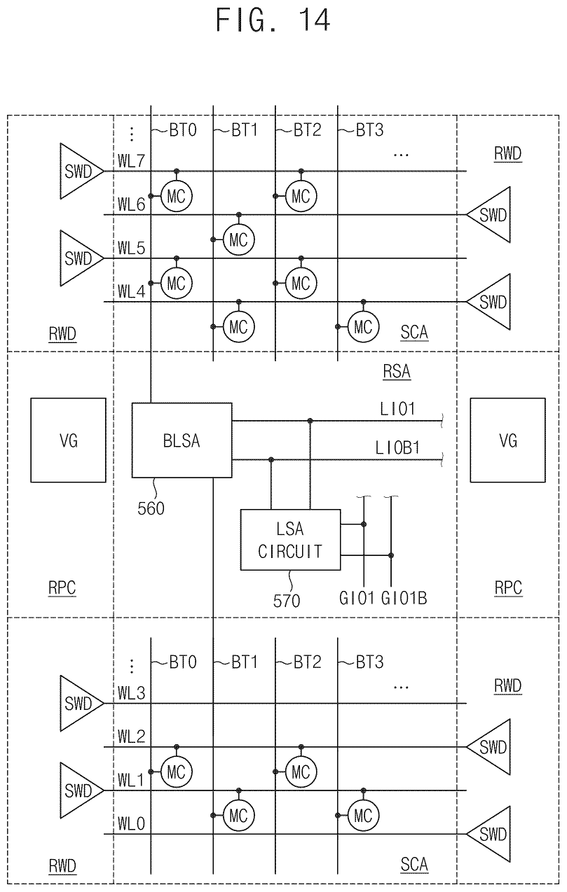

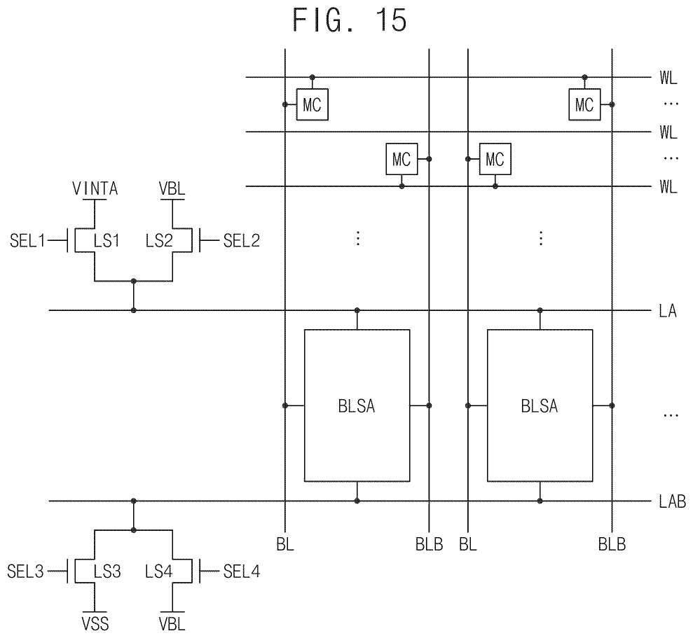

FIGS. 14 and 15 are diagrams illustrating an example of a memory core circuit included in a semiconductor memory device.

Referring to FIG. 14, sub-cell arrays SCA, sense amplifier regions RSA, wordline driver regions RWD, and power and control regions RPC may be arranged in a memory core circuit of a semiconductor memory device.

The sub-cell arrays SCA include a plurality of wordlines WL0 to WL7 extending in a row direction and a plurality of bitlines BT0 to BT3 extending in a column direction, and include memory cells MC arranged at points where the wordlines WL0 to WL7 and the bitlines BT0 to BT3 intersect.

The wordline driver regions RWD include a plurality of sub-wordline drivers SWD for driving the plurality of wordlines WL0 to WL3, respectively. The sense amplifier area RSA include bitline sense amplifiers (BLSA) 560 and a local sense amplifier circuit (LSA circuit) 570 connected to the bitlines BT0 to BT3 of the sub-cell arrays SCA in an open bitline structure. The bitline sense amplifier BLSA may amplify the difference in voltage levels detected on the bitlines BT0 to BT3 and provide the amplified voltage level difference to a local input-output line pair LIO1 and LIOB1. A power circuit that supplies power to each sub-peripheral circuit and a control circuit that controls the operation of each sub-peripheral circuit are arranged in the power and control area RPC. Although voltage drivers VG that may be included in the power and control area RPC are illustrated in FIG. 14, the circuit configuration is not limited thereto.

Referring to FIG. 15, the voltage selection transistors LS1 and LS2 may apply an internal voltage VINTA or a precharge voltage VBL to the control line LA based on the selection signals SEL1 and SEL2. In addition, the voltage selection transistors LS3 and LS4 may apply a ground voltage VSS or a precharge voltage VBL to the complementary control line LAB based on the selection signals SEL3 and SEL4. In the semiconductor memory device, when the selected wordline WLs is activated by the row address, data of a plurality of memory cells MC connected to the selected wordline WLs are transferred to the bitline pair BL and BLB, and the bitline sense amplifier BLSA detects and amplifies the voltage differences of the bitline pairs BL and BLB based on the voltage of the control line LA and the voltage of the complementary control line LAB.

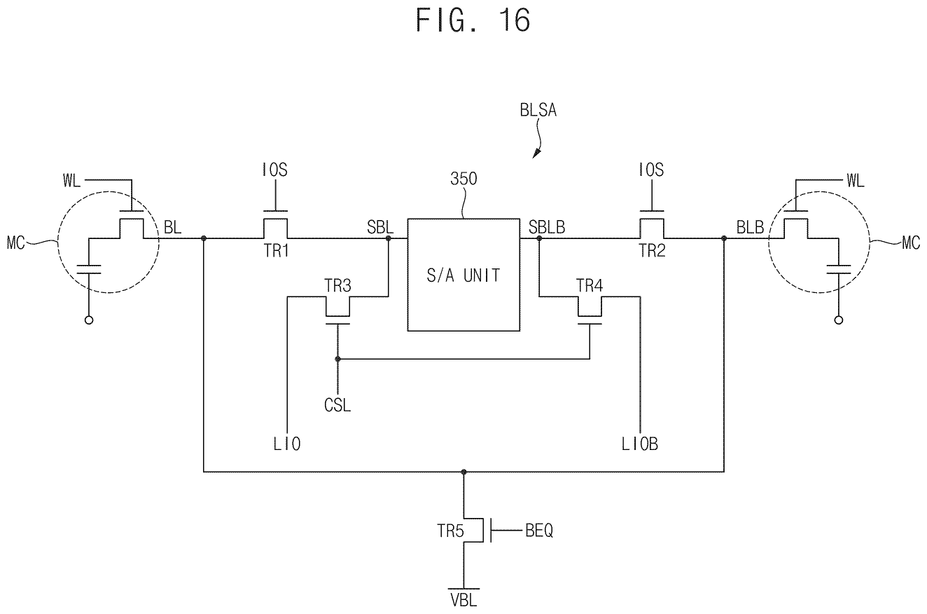

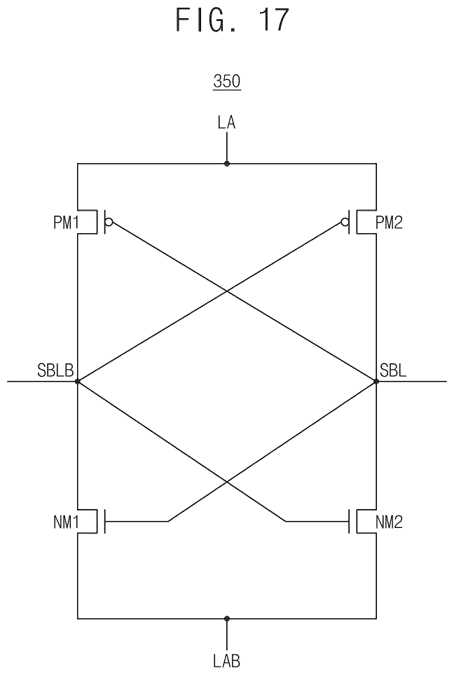

FIG. 16 is a diagram illustrating an example of a bitline sense amplifier included in a semiconductor memory device, and FIG. 17 is a diagram illustrating an example of a sense amplifier included in the bitline sense amplifier of FIG. 16.

Referring to FIG. 16, a bitline sense amplifier BLSA coupled to a bitline BL and a complementary bitline BLB may include transistors TR1 to TR5 and a sense amplification unit (S/A UNIT) 350.

The sense amplification unit 350 is coupled to a sense bitline SBL and a complementary sense bitline SBLB. The sense amplification unit 350 may be configured to amplify or maintain the level of the sense bitline SBL and the complementary sense bitline SBLB.

In some implementations, as shown in FIG. 17, the sense amplification unit 350 may include an N-type sense amplifier and a P-type sense amplifier. For example, the N-type sense amplifier may include a first N-type transistor NM1 and a second N-type transistor NM2. The P-type sense amplifier may include a first P-type transistor PM1 and a second P-type transistor PM2. The N-type sense amplifier and the P-type sense amplifier may amplify the amount of voltage change of the bitline BL according to a specified ratio during the bitline sense operation.

A first isolation transistor TR1 is connected between the bitline BL and the sense bitline SBL and operates in response to an isolation signal ISO. The second isolation transistor TR2 is connected between the complementary bitline BLB and the complementary sense bitline SBLB and operates in response to the isolation signal ISO.

The first and second isolation transistors TR1 and TR2 may operate to isolate the sense amplification unit 350 from the bitline BL and the complementary bitline BLB in response to the isolation signal ISO. By isolating the sense amplification unit 350 from the bitline BL and complementary bitline BLB using the first and second isolation transistors TR1 and TR2, signal disturbances caused by voltages on the bitline BL and complementary bitline BLB may be prevented.

A first column select transistor TR3 is connected between the local input-output line LIO and the sense bitline SBL and operates in response to a column select signal CSL. A second column select transistor TR4 is connected between the complementary local input-output line LIOB and the complementary sense bitline SBLB and operates in response to the column select signal CSL.

As the first and second column select transistors TR3 and TR4 are operated by the column select signal CSL, the read data maintained in the sense amplification unit 350 may be provided to the outside (e.g., the memory controller 1200) via the local input-output line LIO and the complementary local input-output line LIOB, or the write data may be stored in the sense amplification unit 350 from the outside via the local input-output line LIO and the complementary local input-output line LIOB. For example, by turning on the first and second column select transistors TR3 and TR4 by the column select signal CSL, a data output operation corresponding to a read command RD or a data input operation corresponding to a write command WR may be performed.

A precharge transistor TR5 may equalize the bitline BL and the complementary bitline BLB to a precharge voltage VBL in response to a bitline equalization signal BEQ.

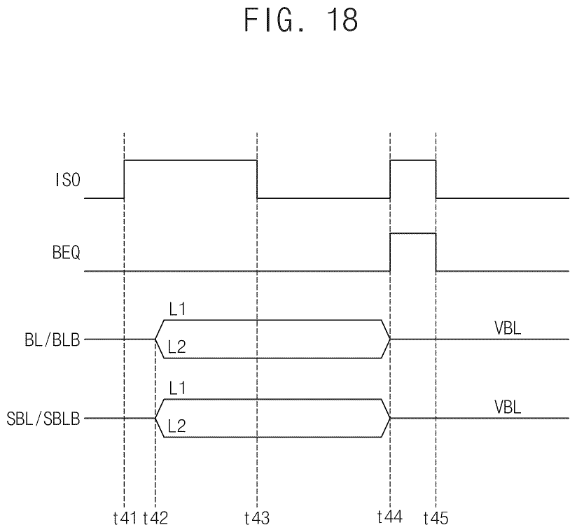

FIG. 18 is a timing diagram illustrating an example of operation of the bitline sense amplifier of FIG. 16.

Referring to FIGS. 16 and 18, during time periods t41 to t43, the isolation signal ISO may be enabled at a logic high level. In response to activation of the selected wordline WLs, at time point t42, the voltage on the bitline BL and the complementary bitline BLB may change to a first level L1 and a second level L2, respectively, as shown in FIG. 18. Further, since the first and second isolation transistors TR1 and TR2 are turned on in response to the activation of the isolation signal ISO, the sense bitline SBL and the complementary sense bitline SBLB electrically connected to the bitline BL and the complementary bitline BLB may also change to the first level L1 and the second level L2, respectively.

Thereafter, the selected wordline WLs may be deactivated, and the isolation signal ISO may be deactivated to a logic low level at time point t43. In response to the logic low level isolation signal ISO, the first and second isolation transistors TR1 and TR2 may be turned off, thereby isolating the bitline BL and the sense bitline SBL from each other, and the complementary bitline BLB and the complementary sense bitline SBLB from each other.

Subsequently, the isolation signal ISO and bitline equalization signal BEQ may be activated at logic high level during time periods t44 to t45. In response to the logic high-level isolation signal ISO and bitline equalization signal BLEQ, the precharge transistor TR5 and the first and second isolation transistors TR1 and TR2 are turned on, and the bitline BL, complementary bitline BLB, sense bitline SBL, and complementary sense bitline SBLB are at the same level (e.g., precharge voltage VBL) as each other.

In some implementations, the control signals ISO, CSL, and BEQ described with reference to FIGS. 16 and 18 may be controlled by the control logic 1410 of FIG. 4. The control logic 1410 may generate the control signals ISO, CSL, and BLEQ in response to an activation command ACT, a write command WR, a read command RD, a signal from the timing controller 1413, and so on.

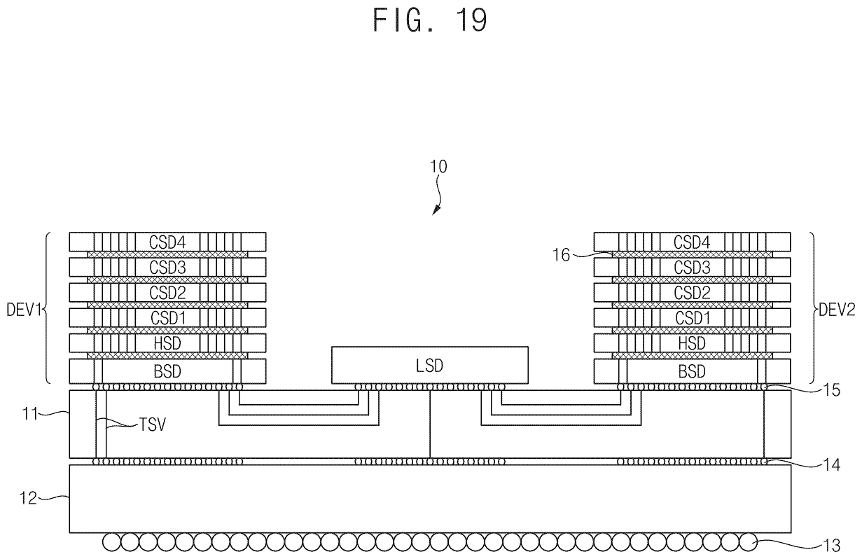

FIG. 19 is a diagram illustrating an example of a stacked memory device.

Referring to FIG. 19, the memory system may be implemented as a multi-chip package 10. The multi-chip package 10 includes a package substrate 12 and an interposer 11 mounted on the package substrate 12. The interposer 11 may be electrically coupled to the package substrate 12 via C4 bumps 14, pads, or any other conductive contact. The package substrate 12 may be connected to an external device via contact members 13 formed on the lower surface of the package substrate 12, such as balls in a ball grid array (BGA). The interposer 11 may include a metal layer forming conductive traces through-silicon via (TSV) and/or other conductive contacts or interconnections. Conductive interconnects within the interposer provide connections for devices mounted on the interposer 11 and/or conductive contacts on the package substrate 12. For example, the interposer 11 may include interconnects for connecting the logic die LSD to memory devices, such as HBM stacks DEV1 and DEV2. The interposer 11 may include an active device (e.g., a die that includes transistors or other active components) or a passive device (e.g., a die that does not include active components). In some implementations, the HBM stacks DEV1 and DEV2 are connected to the logic die LSD via a bridge die (e.g., an embedded multi-die interconnect bridge (EMIB)) or via another technique for combining chips in a multi-chip package. Although two HBM stacks DEV1 and DEV2 are shown, the multi-chip package 10 may include a single HBM stack or additional HBM stacks.

The multi-chip package includes the logic die LSD mounted on an interposer 11. The logic die may be or include system-on-chip (SoC), field-programmable gate array (FPGA), central processing unit (CPU), accelerator, graphics processing unit (GPU), or other logic die. The logic die LSD is coupled to the HBM stacks DEV1 and DEV2 via interconnects on the interposer 11, the EMIB, or other interconnects between the logic die LSD and the HBM stacks DEV1 and DEV2.

As shown in FIG. 19, the HBM stacks DEV1 and DEV2 include a buffer semiconductor die BSD and a plurality of memory semiconductor dies or a plurality of core semiconductor dies CSD1 through CSD4, wherein the buffer semiconductor die BSD and the plurality of core semiconductor dies CSD1 through CSD4 are electrically connected to each other via a plurality of vertical conductive paths including through-silicon vias TSV. Memory cells are distributed and disposed in the plurality of core semiconductor dies CSD1 through CSD4. The HBM stacks DEV1 and DEV2 may be internally and externally connected via contact means 15 and 16, e.g., microbumps.

Each of the HBM stacks may include a heterogeneous semiconductor die HSD. The heterogeneous semiconductor die HSD is stacked with the buffer semiconductor die BSD and the plurality of core semiconductor dies CSD1 through CSD4, and includes a plurality of power capacitors.

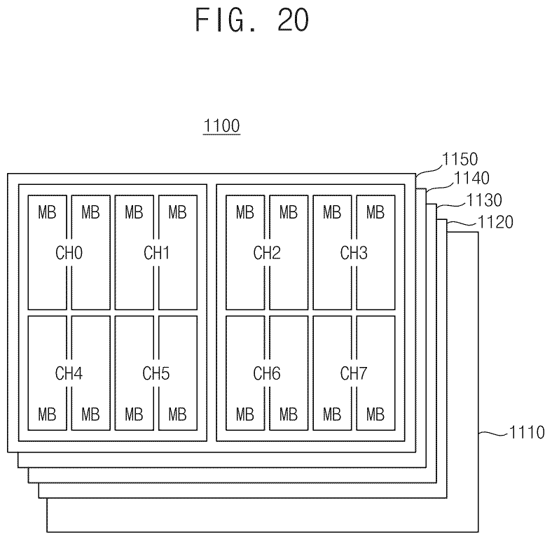

FIG. 20 is a diagram illustrating an example of a stacked memory device.

FIG. 20 illustrates an example of the structure of a high-bandwidth memory. Referring to FIG. 20, a high-bandwidth memory (HBM) 1100 may include a structure in which a plurality of semiconductor dies 1120, 1130, 1140 and 1150 are stacked. One of the plurality of semiconductor dies 1120, 1130, 1140 and 1150 may correspond to the heterogeneous semiconductor die and the others may correspond to the core semiconductor dies as described above. The core semiconductor dies may be referred to as DRAM semiconductor dies.

The high-bandwidth memory may be optimized for high-bandwidth operation of the stacked structure through a plurality of independent interfaces called channels. According to the HBM standard, each DRAM stack may support a variety of channels.

Although FIG. 20 illustrates an example in which four semiconductor dies are stacked, the number of semiconductor dies is not limited thereto. Each semiconductor die may provide additional memory capacity and additional channels to the stacked structure. Each channel provides access to an independent set of DRAM banks. A request from one channel does not access data attached to another channel. The channels are independently clocked and do not need to be synchronized with each other. FIG. 20 illustrates an example in which the memory banks MB of each DRAM semiconductor die are grouped into eight independent channels CH0-CH7, but the grouping(s) are not limited thereto.

The high-bandwidth memory 1100 may include a buffer die or interface die 1110 located at the bottom of the stack structure and providing signal redistribution and other functions. Functions typically implemented in the DRAM semiconductor dies may be implemented in this interface die 1110.

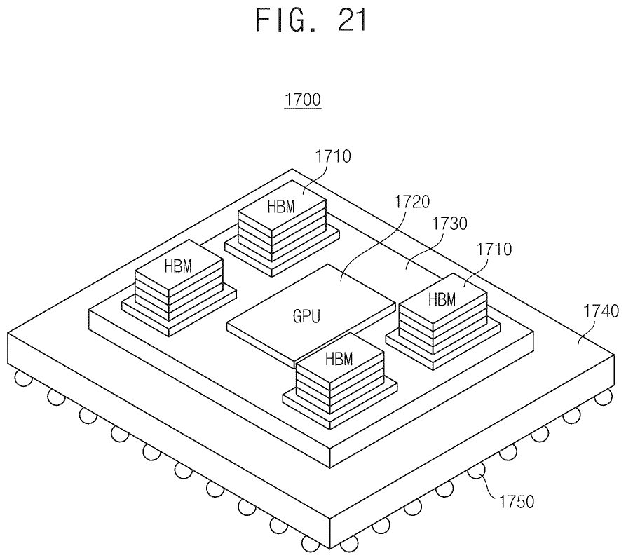

FIG. 21 is a diagram illustrating an example of a structure of a semiconductor package including a semiconductor memory device.

Referring to FIG. 21, a semiconductor package 1700 includes one or more stacked memory devices 1710 and a graphics processing unit (GPU) 1720. The stacked memory devices 1710 and the GPU 1720 may be mounted on an interposer 1730, and the interposer 1730 on which the stacked memory devices 1710 and the GPU 1720 are mounted may be mounted on a package substrate 1740. The GPU 1720 may perform substantially the same function as the aforementioned memory controller or may include a memory controller therein. The GPU 1720 may store data generated or used in graphic processing in one or more stacked memory devices 1710.

The stacked memory device 1710 may be implemented in various forms, and, in some implementations, the stacked memory device 1710 may be a memory device in the form of a high-bandwidth memory (HBM) in which a plurality of layers are stacked. Accordingly, the stacked memory device 1710 may include a buffer semiconductor die, a heterogeneous semiconductor die and a plurality of core semiconductor dies.

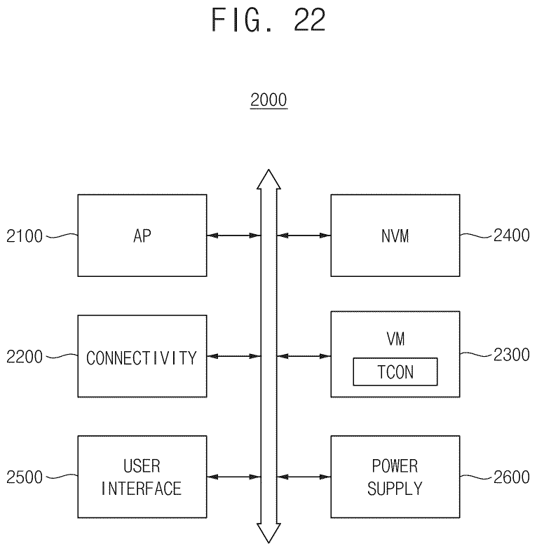

FIG. 22 is a block diagram illustrating an example of a mobile system including a semiconductor memory device.

Referring to FIG. 22, a mobile system 2000 includes an application processor 2100, a connectivity unit 2200, a semiconductor memory device 2300, a nonvolatile semiconductor memory device 2400, a user interface 2500 and a power supply 2600. The mobile system 2000 may be any mobile system, such as a mobile phone, a smart phone, a personal digital assistant (PDA), a portable multimedia player (PMP), a digital camera, a music player, a portable game console, a navigation system, etc.

The application processor 2100 may execute applications that provide an Internet browser, a game, a video, etc. The connectivity unit 2200 may perform wireless or wired communication with an external device. The semiconductor memory device 2300 may store data processed by the application processor 2100 or may operate as a working memory.

The nonvolatile semiconductor memory device 2400 may store user data and a boot image for booting the mobile system 2000. The user interface 2500 may include one or more input devices such as a keypad, a touch screen, and/or one or more output devices such as a speaker, a display device. The power supply 2600 may supply an operation voltage of the mobile system 2000.

According to some implementations, the semiconductor memory devices of FIGS. 19 to 22 (e.g., memory device 2300) may include a timing controller TCON. As described above, the timing controller TCON may control activation of a selected word line based on commands transmitted from a memory controller (e.g., an application processor (2100)).

As described above, the semiconductor memory devices, the memory systems, and the methods of operating the memory systems described herein may reduce disturbance inside the semiconductor memory device and improve the performance and reliability of the semiconductor memory device, by reducing the activation time of the selected wordline based on the read precharge command and the write precharge command. The memory devices can perform different operations for the write precharge command and the write precharge command to thereby provide improved performance.

Aspects of the present disclosure may be applied to any electronic device and system. For example, the disclosure may be applied to (e.g., the described memory devices and controllers may be included in) systems such as a memory card, a solid state drive (SSD), an embedded multimedia card (eMMC), a universal flash storage (UFS), a mobile phone, a smart phone, a personal digital assistant (PDA), a portable multimedia player (PMP), a digital camera, a camcorder, a personal computer (PC), a server computer, a workstation, a laptop computer, a digital TV, a set-top box, a portable game console, a navigation system, a wearable device, an internet of things (IoT) device, an internet of everything (IoE) device, an e-book, a virtual reality (VR) device, an augmented reality (AR) device, a server system, an automotive driving system, etc.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of various examples. Although these examples have been described, those skilled in the art will readily appreciate that many modifications are possible without materially departing from the scope of the present disclosure.

What is claimed is:

1. A semiconductor memory device comprising:
a plurality of memory cells connected to a plurality of wordlines and a plurality of bitlines,
wherein the semiconductor memory device is configured to:
based on an activation command received from a memory controller:
activate a selected wordline of the plurality of wordlines, and
deactivate the selected wordline after a first activation reference time has elapsed from a time point of activating the selected wordline;
maintain the selected wordline in a deactivated state based on a read precharge command received from the memory controller; and
reactivate the selected wordline based on a write precharge command received from the memory controller.

2. The semiconductor memory device of claim 1, wherein the semiconductor memory device is configured to maintain the selected wordline in the deactivated state after receiving at least one read command and no write command, wherein the at least one read command and no read command is received after the activation command is received and before the read precharge command is received.

3. The semiconductor memory device of claim 1, wherein the semiconductor memory device is configured to reactivate the selected wordline after receiving at least one write command, wherein the at least one write command is received after the activation command is received and before the write precharge command is received.

4. The semiconductor memory device of claim 1, wherein the semiconductor memory device is configured to precharge the plurality of bitlines with a precharge voltage based on the read precharge command.

5. The semiconductor memory device of claim 1, wherein the semiconductor memory device is configured to, after reactivating the selected wordline based on the write precharge command, deactivate the selected wordline after a second activation reference time has elapsed from a time point of reactivating the selected wordline.

6. The semiconductor memory device of claim 5, wherein the semiconductor memory device is configured to precharge the plurality of bitlines with a precharge voltage after the selected wordline is deactivated after the second activation reference time has elapsed.

7. The semiconductor memory device of claim 5, wherein the second activation reference time is longer than the first activation reference time.

8. The semiconductor memory device of claim 1, wherein the semiconductor memory device is configured to perform a read operation based on a read command received from the memory controller, wherein the read command is received after the activation command is received and before the read precharge command is received.

9. The semiconductor memory device of claim 1, wherein the semiconductor memory device is configured to perform a write operation based on the write precharge command, wherein the write operation comprises storing write data in memory cells connected to the selected wordline.

10. The semiconductor memory device of claim 1, wherein the semiconductor memory device is configured to:
receive a second activation command from the memory controller after a first precharge reference time has elapsed from a time point of receiving the read precharge command from the memory controller, and
receive a third activation command from the memory controller after a second precharge reference time has elapsed from a time point of receiving the write precharge command from the memory controller.

11. The semiconductor memory device of claim 10, wherein the second precharge reference time is longer than the first precharge reference time.

12. The semiconductor memory device of claim 1, further comprising:
mode registers configured to store control values for controlling operations of the semiconductor memory device,
wherein the semiconductor memory device is configured to determine the first activation reference time based on a control value stored in a first mode register of the mode registers.

13. The semiconductor memory device of claim 1, further comprising:
a timing controller configured to generate a wordline enable signal indicating an activation timing of the selected wordline based on the activation command and the write precharge command.

14. The semiconductor memory device of claim 13, wherein the timing controller is configured to:
activate the wordline enable signal for first activation reference time based on the activation command; and
activate the wordline enable signal for a second activation reference time, longer than the first activation reference time, based on the write precharge command.

15. The semiconductor memory device of claim 1, wherein the plurality of memory cells are dynamic random access memory (DRAM) cells, and wherein each DRAM cell includes one cell transistor and one capacitor.

16. A memory system comprising:
a semiconductor memory device including a plurality of memory cells connected to a plurality of wordlines and a plurality of bitlines; and
a memory controller configured to control the semiconductor memory device,
wherein the memory controller is configured to:
transmit a first activation command to the semiconductor memory device at a first time point;
transmit at least one read command and no write command to the semiconductor memory device in a time period from the first time point to a second time point;
transmit a read precharge command to the semiconductor memory device at the second time point;
transmit a second activation command to the semiconductor memory device at a third time point;
transmit at least one write command to the semiconductor memory device in a time period from the third time point to a fourth time point; and
transmit a write precharge command to the semiconductor memory device at the fourth time point, and
wherein the semiconductor memory device is configured to control activation of one or more selected wordlines of the plurality of wordlines based on the first activation command, the second activation command, the read precharge command, and the write precharge command, and
wherein the semiconductor memory device is configured to perform different operations based on receiving the read precharge command or the write precharge command.

17. The memory system of claim 16, wherein the semiconductor memory device is configured to activate a first selected wordline of the plurality of wordlines based on the first activation command and deactivate the first selected wordline after a first activation reference time has elapsed from a time point of activating the first selected wordline.

18. The memory system of claim 16, wherein the semiconductor memory device is configured to:
activate a first selected wordline of the plurality of wordlines based on the first activation command;
maintain the first selected wordline in a deactivated state based on the read precharge command;
activate a second selected wordline of the plurality of wordlines based on the second activation command; and
reactivate the second selected wordline based on the write precharge command.

19. A method of operating a memory system including a semiconductor memory device and a memory controller configured to control the semiconductor memory device, the method comprising:
transmitting, by the memory controller, a first activation command to the semiconductor memory device at a first time point;
transmitting, by the memory controller, at least one read command and no write command to the semiconductor memory device in a time period from the first time point to a second time point;
transmitting, by the memory controller, a read precharge command to the semiconductor memory device at the second time point;
transmitting, by the memory controller, a second activation command to the semiconductor memory device at a third time point;
transmitting, by the memory controller, at least one write command to the semiconductor memory device in a time period from the third time point to a fourth time point;
transmitting, by the memory controller, a write precharge command to the semiconductor memory device at the fourth time point; and
controlling, by the semiconductor memory device, activation of one or more selected wordlines based on the first activation command, the second activation command, the read precharge command, and the write precharge command.

20. The method of claim 19, wherein controlling the activation of the one or more selected wordlines includes:
activating a first selected wordline based on the second activation command;
deactivating the first selected wordline after a first activation reference time has elapsed from a time point of activating the first selected wordline;
reactivating the first selected wordline based on the write precharge command; and
deactivating the first selected wordline after a second activation reference time has elapsed from a time point of reactivating the selected wordline.
